(19) United States
(12) Patent Application Publication
(10) Pub. No.: US 2019/0346496 A1
(43) Pub. Date: Nov. 14, 2019

(54) Method for Determining Amplitude and Phase of Stratified Current of Overhead Wire

(71) Applicant: South China University of Technology

(72) Inventors: Gang Liu, Guangzhou City (CN); Yuan Chen, Guangzhou City (CN); Yang LI, Guangzhou City (CN); Yiqing Wang, Guangzhou City (CN)

(21) Appl. No.: 16/483,936

(22) PCT Filed: Dec. 15, 2017
(86) PCT No.: PCT/CN2017/116392

§ 371 Date: Aug. 6, 2019

(30) Foreign Application Priority Data
Feb. 10, 2017 (CN) 201710073379.2

(51) Int. Cl. G01R 25/02; G01R 19/00

(52) U.S. Cl. CPC G01R 25/02; G01R 19/0092

(57) ABSTRACT

The present invention discloses a method for determining the amplitude and phase of a stratified current of an overhead wire, the method comprising the following steps: S1, determining the specification, the size and main technical parameters of a wire; S2, calculating mutual inductances between conductors within a single-phase wire and the self-inductance thereof; S3, calculating mutual inductance reactance between conductors within the single-phase wire of a three-phase system and the self-inductance reactance thereof; and S4, calculating the distribution of currents in each layer. The method takes into account the magnetic field coupling effect between conductors within a wire, so as to accurately calculate the current flowing through conductors in each layer within the wire, and accurately reflect a phase relationship between conductors in each layer.

### TECHNICAL FIELD

The present invention relates to the technical field of calculating the temperature gradient distribution inside an overhead wire, and particularly to a method for determining the amplitude and phase of a stratified current of an overhead wire.

### BACKGROUND ART

The equation of states of an overhead wire finds, based on the temperature-tension in a known state, the temperature or tension in another state, thereby finding the sag of the wire. The equation of states simplifies the structural features of an overhead wire during the derivation: it is considered that the entire wire is an isothermal body and the cross-sectional stress distribution is uniformly distributed. However, the overhead wire is mostly a steel-cored aluminum stranded wire, which are stranded by several strands of conductors, so that there is an air gap between the conductors in each layer, of which the heat transfer coefficient is larger relative to the metal conductor, and the temperature mainly falls in the air, in addition, the heat dissipation condition of the outer surface is better than that of the inner part, so the internal temperature of the steel-cored aluminum stranded wires is higher than the temperature of the outer layer. Thus, the high temperature range of the wire is borne by the steel core, and the radial temperature difference can reach more than ten degrees. To this end, accurately calculating the temperature of the steel core or the radial temperature difference of the steel wire aluminum stranded wire of the overhead wire will play an important role in improving the calculation accuracy of such a model.

At present, researchers at home and abroad have done some research on the radial temperature distribution of the overhead wire, and have achieved many outstanding outcomes. For example, V. T. Morgan et al. consider the contact thermal resistance of the air gap and the air thermal resistance, and think that the heat generation rate of a conductor is uniformly distributed on a cross section of the conductor. Based on this, the radial temperature calculation formula is deduced in detail. W. Z. Black establishes a heat transfer equation under the condition that the current is distributed in DC series and parallel. The radial heat transfer coefficient is divided and valued under different current loads, different wind speeds and different tension conditions. At home, Ying Zhanfeng et al. establish, in combination with a parameter identification and thermoelectric analogy method, a radial temperature thermal path model, which was verified by experiments. However, in the above review, some simplify the actual structure of the wire, and think that the steel-cored aluminum stranded wire is a coaxial double conductor. Although some consider the stranded structure of the wire, the effects of a skin effect on the current distribution and ohmic loss still have not been considered in calculating the heat generation rate of conductors in each layer, while the above two aspects are main factors affecting the existence of the radial gradient. Therefore, accurately calculating the current distribution of the conductors in each layer within the overhead wire at an AC frequency and the actual heat generation rate of the conductors in each layer will be crucial for accurately evaluating the temperature of the steel core.

### SUMMARY OF THE INVENTION

An object of the present invention is to overcome the above-described defects in the prior art. A method for determining the amplitude and phase of a stratified current of an overhead wire is provided.

The object of the present invention can be achieved by taking the following technical solutions:

A method for determining the amplitude and phase of a stratified current of an overhead wire, the method comprising:

S1, determining the specification, the size and main technical parameters of a wire, the step specifically being as follows:

S101, determining the number of layers of the overhead wire and the number of conductors in each layer and the planned size thereof; and

S102, determining the material of the conductors in each layer and the corresponding resistivity and magnetic permeability;

S2, calculating mutual inductances between conductors within a single-phase wire and the self-inductance thereof, the step specifically being as follows:

S201, calculating the mutual inductance between a conductor layer i and a conductor layer j within the single-phase wire; and

S202, calculating the self-inductance of the conductor layer i within the single-phase wire;

S3, calculating mutual inductance reactance between conductors of a three-phase system and the self-inductance reactance thereof, the step specifically being as follows:

S301, calculating the total mutual inductance reactance between the conductor layer i and the conductor layer j within an A-phase wire in a three-phase system; and

S302, calculating the self-inductance reactance of the conductor layer i within the A-phase wire in the three-phase system; and

S4, calculating the distribution of currents in each layer.

Further, step S101 is specifically as follows:

numbering the wires and determining the radius of the overhead wire and the radius of each conductor, wherein each phase of the three-phase wire has m layers, which are numbered, from inside to outside, as 1, 2, . . . m, there are n conductors in each layer within a wire, no distinction is made between the conductors in each layer, and the three-phase wires are only distinguished by subscripts a, b and c in derivation; and

in terms of current, using İᵢ to indicate the total current of the layer i, and using İᵢ′ to indicate the current on a wire in the layer i, that is İᵢ=nİᵢ′,

where n is the number of conductors in the layer i, and İᵢ′ appears only in the result analysis to compare effects of a skin effect.

Further, step S102 is specifically as follows:

determining the resistivity and magnetic permeability of various conductors based on that the overhead wire is a steel-cored aluminum stranded wire, an aluminum stranded wire and a copper wire.

Further, the calculation formula for the mutual inductance Mₐᵢₐⱼ in step S201 is specifically as follows:

$${M}_{aiaj} = \frac{{μ}_{0}}{2 π} [ Ln ( \frac{2 l}{{D}_{ij}} - 1 ) ] , \\ wherein {D}_{ij} = \sqrt[mn]{{\prod }_{k = 1}^{m} {\prod }_{i = 1}^{n} [ {r}_{i}^{2} + {r}_{j}^{2} - 2 {r}_{i} {r}_{j} cos ( {θ}_{ik} - {θ}_{j 1} ) ]} ,$$

where m is the number of conductors in the layer i, n is the number of conductors in the layer j, Dⱼᵢ is a geometric mean of distances between conductors between the layer i and the layer j, rᵢ is the distance from the center of circle of a single conductor in the layer i to the center of the wire, rⱼ is the distance from the center of circle of the single conductor in the layer j to the center of the wire, and θᵢₖ−θⱼ₁ is an opening angle between the center of circle of the k^{th} conductor in the layer i and the center of circle of the 1^{st} conductor in the layer j, relative to the total center of circle of the wire.

Further, the calculation formula for the self-inductance Lₐᵢₐᵢ in the step S202 is specifically as follows:

$${L}_{aiaj} = \frac{{μ}_{0}}{2 π} [ Ln ( \frac{2 l}{{D}_{ij}} - 1 ) ] , \\ wherein , {D}_{ij} = \sqrt[m]{{r}_{eq} {\prod }_{k = 2}^{m} [ {r}_{i}^{2} + {r}_{1}^{2} - 2 {r}_{i} {r}_{1} cos ( {θ}_{ik} - {θ}_{i1} ) ]}$$

where m is the number of conductors in the layer i, Dᵢᵢ is a geometric mean of distances between conductors in the layer i, rᵢ is the distance from the center of circle of a single conductor in the layer i to the center of the wire, θᵢₖ−θᵢ₁ is an opening angle between the center of circle of the k^{th} conductor in the layer i and the center of circle of the 1^{st} conductor in the layer i, relative to the total center of circle of the wire, and r_{eq} is an equivalent radius of the first conductor in the layer i.

Further, the step S301 is specifically as follows:

assuming that the system is in three-phase current symmetry, that is

iₐᵢ+i_{bi}+i_{ci}=0

the wire is in three-phase symmetry after alternation and the equivalent distance between wires is D_{eq}, and the distance between the wires is considered to be much greater than the distance between each strand within a one-phase wire, then for the conductor layer i within an A phase wire, a magnetic flux linkage generated by the current in the conductor layer j is:

$$\begin{matrix}{ψ}_{aij} = {M}_{aiaj} {i}_{aj} + {M}_{aibj} {i}_{bj} + {M}_{aicj} {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] {i}_{bj} + \frac{{μ}_{0}}{2 π} [ Ln ( \frac{2 l}{{D}_{eq}} - 1 ) ] {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] ( {i}_{bj} + {i}_{cj} ) \\ = \frac{{μ}_{0}}{2 π} Ln ( \frac{{D}_{eq}}{{D}_{ij}} ) {i}_{aj}\end{matrix}$$

therefore, in a three-phase symmetric system, the total mutual inductance between the conductor layer i within an A-phase wire and the conductor layer j within the A-phase wire is:

$${M}_{aiaj} = \frac{{μ}_{0}}{2 π} [ Ln ( \frac{2 l}{{D}_{ij}} - 1 ) ]$$

and in the three-phase symmetric system, the total mutual inductance reactance between the conductor layer i within the A-phase wire and the conductor layer j within the A-phase wire is:

$${X}_{aij} = {μ}_{0} f Ln ( \frac{{D}_{eq}}{{D}_{ij}} ) .$$

Further, the step S302 is specifically as follows:

in the mutual inductance reactance

$${X}_{aij} = {μ}_{0} f Ln ( \frac{{D}_{eq}}{{D}_{ij}} )$$

making i=j to obtain the self-inductance reactance of the conductor layer i

$${X}_{aii} = {μ}_{0} f Ln ( \frac{{D}_{eq}}{{D}_{ii}} ) .$$

Further, step S4 is specifically as follows:

assuming that in one phase the resistances of each layer from inside to outside is r₁, r₂, r₃ . . . rₘ respectively, and taking a wire segment of unit length, wherein the voltage drops between each layer on the wire segment should be equal, denoted as V, then there is

$$V = {r}_{1} {i}_{1} + j ( {X}_{11} {i}_{1} + {X}_{12} {i}_{2} + {X}_{13} {i}_{3} + … {X}_{1 m} {i}_{m} )$$

$$V = {r}_{2} {i}_{2} + j ( {X}_{21} {i}_{1} + {X}_{22} {i}_{2} + {X}_{23} {i}_{3} + … {X}_{2 m} {i}_{m} )$$

$$V = {r}_{3} {i}_{1} + j ( {X}_{31} {i}_{1} + {X}_{32} {i}_{2} + {X}_{33} {i}_{3} + … {X}_{3 m} {i}_{m} )$$

$$…$$

$$V = {r}_{m} {i}_{1} + j ( {X}_{m 1} {i}_{1} + {X}_{m 2} {i}_{2} + {X}_{m 3} {i}_{3} + … {X}_{m m} {i}_{m} ) ,$$

combining the above formulas and eliminating V and D_{eq} to obtain

$$[ \begin{matrix}{r}_{1} - j {μ}_{0} f Ln \frac{{D}_{11}}{{D}_{12}} \\ {r}_{1} - j {μ}_{0} f Ln \frac{{D}_{11}}{{D}_{13}} \\ … \\ {r}_{1} - j {μ}_{0} f Ln \frac{{D}_{11}}{{D}_{1 m}}\end{matrix} ] [ \begin{matrix}{i}_{1} & 0 & 0 & … & 0 \\ 0 & {i}_{1} & 0 & … & 0 \\ 0 & 0 & {i}_{1} & … & 0 \\ … & & & & \\ 0 & 0 & 0 & … & {i}_{1}\end{matrix} ] = [ \begin{matrix}{r}_{2} + j {μ}_{0} f Ln \frac{{D}_{12}}{{D}_{22}} & j {μ}_{0} f Ln \frac{{D}_{13}}{{D}_{23}} & … & j {μ}_{0} f Ln \frac{{D}_{1 m}}{{D}_{2 m}} \\ j {μ}_{0} f Ln \frac{{D}_{12}}{{D}_{23}} & {r}_{3} + j {μ}_{0} f Ln \frac{{D}_{13}}{{D}_{23}} & … & j {μ}_{0} f Ln \frac{{D}_{12}}{{D}_{3 m}} \\ … & & & \\ j {μ}_{0} f Ln \frac{{D}_{12}}{{D}_{2 m}} & j {μ}_{0} f Ln \frac{{D}_{13}}{{D}_{3 m}} & … & {r}_{4} + j {μ}_{0} f Ln \frac{{D}_{1 m}}{{D}_{mm}}\end{matrix} ] [ \begin{matrix}{i}_{2} \\ {i}_{3} \\ … \\ {i}_{m}\end{matrix} ] , \\ denoting T = {[ \begin{matrix}{r}_{1} - j {μ}_{0} f Ln \frac{{D}_{11}}{{D}_{12}} & {r}_{1} - j {μ}_{0} f Ln \frac{{D}_{11}}{{D}_{13}} & … & {r}_{1} - j {μ}_{0} f Ln \frac{{D}_{11}}{{D}_{1 m}}\end{matrix} ]}^{T}$$

$$X = [ \begin{matrix}{r}_{2} + j {μ}_{0} f Ln \frac{{D}_{12}}{{D}_{22}} & j {μ}_{0} f Ln \frac{{D}_{13}}{{D}_{23}} & … & j {μ}_{0} f Ln \frac{{D}_{1 m}}{{D}_{2 m}} \\ j {μ}_{0} f Ln \frac{{D}_{12}}{{D}_{23}} & {r}_{3} + j {μ}_{0} f Ln \frac{{D}_{13}}{{D}_{23}} & … & j {μ}_{0} f Ln \frac{{D}_{12}}{{D}_{3 m}} \\ … & & & \\ j {μ}_{0} f Ln \frac{{D}_{12}}{{D}_{2 m}} & j {μ}_{0} f Ln \frac{{D}_{13}}{{D}_{3 m}} & … & {r}_{4} + j {μ}_{0} f Ln \frac{{D}_{1 m}}{{D}_{mm}}\end{matrix} ]$$

$$then [ \begin{matrix}{i}_{2} \\ {i}_{3} \\ … \\ {i}_{4}\end{matrix} ] = {X}^{- 1} T [ \begin{matrix}{i}_{1} & 0 & 0 & … & 0 \\ 0 & {i}_{1} & 0 & … & 0 \\ 0 & 0 & {i}_{1} & … & 0 \\ … & & & & \\ 0 & 0 & 0 & … & {i}_{1}\end{matrix} ] ,$$

when vectors are used for representation

$$[ \begin{matrix}{\dot{I}}_{2} \\ {\dot{I}}_{3} \\ … \\ {\dot{I}}_{4}\end{matrix} ] = {X}^{- 1} T [ \begin{matrix}{\dot{I}}_{1} & 0 & 0 & … & 0 \\ 0 & {\dot{I}}_{1} & 0 & … & 0 \\ 0 & 0 & {\dot{I}}_{1} & … & 0 \\ … & & & & \\ 0 & 0 & 0 & … & {\dot{I}}_{1}\end{matrix} ] ,$$

by means of the solution described above, the ratio distribution between currents of each layer is obtained, and by adding the formula

İ₁+İ₂+İ₃+ . . . İₘ=İ_{Σ}

the current distribution in each layer is calculated.

Compared with the prior art the present invention has the following advantages and effects:

The present invention discloses a method for determining the amplitude and phase of a stratified current of an overhead wire. In combination with the actual structure, specification, size and physical technical parameters of the LGJ300/40 wire, taking into account the electromagnetic coupling effects between conductors, the current flowing through conductors in each layer is deduced, and the accuracy of the model is compared by means of an electromagnetic simulation software ANSOFT MAXWELL.

### BRIEF DESCRIPTION OF THE DRAWINGS

FIG. 1 is a flowchart of a method for determining the amplitude and phase of a stratified current of an overhead wire disclosed in the present invention.

### DETAILED DESCRIPTION OF EMBODIMENTS

In order to make the objectives, technical solutions and advantages of embodiments of the present invention clearer, the technical solutions in embodiments of the present invention will be clearly and completely described below with reference to the accompanying drawings in the embodiments of the present invention. Apparently, the described embodiments are a part, but not all of the embodiments of the present invention. All other embodiments obtained by those of ordinary skill in the art based on the embodiments of the present invention without any creative effort shall fall within the protection scope of the present invention. On the basis of the embodiments of the present invention, all the other embodiments obtained by a person skilled in the art without any inventive effort shall fall within the scope of protection of the present invention.

### Embodiment

In this embodiment, in combination with an LGJ300/40 type A phase wire being used as an object to be calculated, a method for calculating a stratified current of an overhead wire is proposed, however, the method is not limited to the LGJ300/40 type wire, wherein the 2D cross-section view of the LGJ 300/40 type wire consists of four layers, which are, from the inside to the outside, a steel core having a radius of 1.33 mm of which a center of circle is the center of the wire, six steel cores having a radius of 1.33 mm of which the centers of circle are uniformly spaced and distributed in a circle with a radius of 2.66 mm, nine aluminum cores having a radius of 1.995 mm of which the centers of circle are uniformly spaced and distributed in a circle with a radius of 5.985 mm, and fifteen aluminum cores having a radius of 1.995 mm of which the centers of circle are uniformly spaced and distributed in a circle with a radius of 9.975 mm, respectively.

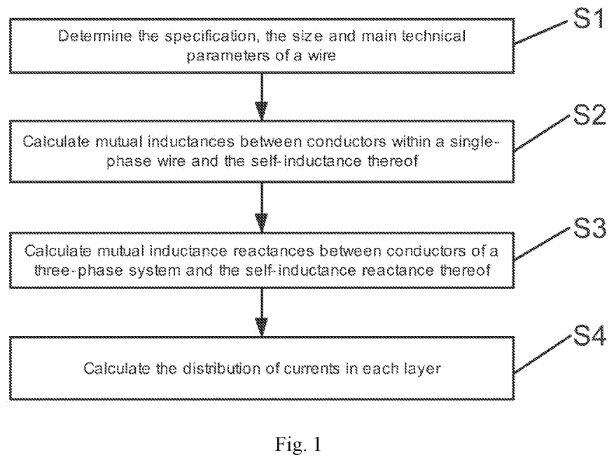

As in FIG. 1, a flowchart of a method for determining the amplitude and phase of a stratified current of an overhead wire is disclosed, the method specifically comprising the following steps:

S1, determining the specification, the size and main technical parameters of a wire, the step specifically further comprising the following sub-steps:

S101, determining the number of layers of the overhead wire and the number of conductors in each layer and the planned size thereof;

In a specific embodiment, the 2D cross-section view of the LGJ 300/40 type wire consists of four layers, which are, from the inside to the outside, a steel core having a radius of 1.33 mm of which a center of circle is the center of the wire, six steel cores having a radius of 1.33 mm of which the centers of circle are uniformly spaced and distributed in a circle with a radius of 2.66 mm, nine aluminum cores having a radius of 1.995 mm of which the centers of circle are uniformly spaced and distributed in a circle with a radius of 5.985 mm, and fifteen aluminum cores having a radius of 1.995 mm of which the centers of circle are uniformly spaced and distributed in a circle with a radius of 9.975 mm, respectively.

in terms of current, using İᵢ to indicate the total current of the layer i, and using İᵢ′ to indicate the current on a wire inside the layer i, that is

İᵢ=nİᵢ,

where n is the number of conductors in the layer i, and İᵢ′ appears only in the result analysis to compare effects of a skin effect.

S102, determining the material of the conductors in each layer and the corresponding resistivity and magnetic permeability;

In a specific embodiment, the material of the conductors in the first and second layers within an overhead wire is steel with a resistivity of 5×10-7 Ωm. Since the metal steel is a ferromagnetic material which will change as the current changes, and the value of relative magnetic permeability varies from 1 to 2000. The material of the conductors in the third and fourth layers is aluminum with a resistivity of 2.83×10-8 Ωm, which is a non-ferromagnetic material, and the value of the relative magnetic permeability is 1.0.

S2, calculating mutual inductances between conductors within an A-phase wire and the self-inductance thereof, the step specifically comprising the following sub-steps:

S201, calculating the mutual inductance between a conductor layer i and a conductor layer j within an A-phase wire;

$${M}_{aiaj} = \frac{{μ}_{0}}{2 π} [ Ln ( \frac{2 l}{{D}_{ij}} - 1 ) ] , \\ wherein {D}_{ij} = \sqrt[mn]{{\prod }_{k = 1}^{m} {\prod }_{i = 1}^{n} [ {r}_{i}^{2} + {r}_{j}^{2} - 2 {r}_{i} {r}_{j} cos ( {θ}_{ik} - {θ}_{j 1} ) ]} ,$$

where m is the number of conductors in the layer i, n is the number of conductors in the layer j, Dᵢⱼ is a geometric mean of distances between conductors between the layer i and the layer j, rᵢ is the distance from the center of circle of a single conductor in the layer i to the center of the wire, rⱼ is the distance from the center of circle of the single conductor in the layer j to the center of the wire, and θⱼₖ−θⱼ₁ is an opening angle between the center of circle of the k^{th} conductor in the layer i and the center of circle of the 1^{st} conductor in the layer j, relative to the total center of circle of the wire.

S202, calculating the self-inductance of the conductor layer i within the A-phase wire;

$${L}_{aiaj} = \frac{{μ}_{0}}{2 π} [ Ln ( \frac{2 l}{{D}_{ij}} - 1 ) ] , \\ wherein , {D}_{ii} = \sqrt[m]{{r}_{eq} {\prod }_{k = 2}^{m} [ {r}_{i}^{2} + {r}_{1}^{2} - 2 {r}_{i} {r}_{1} cos ( {θ}_{ik} - {θ}_{i 1} ) ]} ,$$

where m is the number of conductors in the layer i, Dᵢᵢ is a geometric mean of distances between conductors in the layer i, rᵢ is the distance from the center of circle of a single conductor in the layer i to the center of the wire, θᵢₖ−θᵢ₁ is an opening angle between the center of circle of the k^{th} conductor in the layer i and the center of circle of the 1^{st} conductor in the layer i, relative to the total center of circle of the wire, and r_{eq} is an equivalent radius of the first conductor in the layer i.

S3, calculating mutual inductance reactance between conductors within each single-phase wire of a three-phase system and the self-inductance reactance thereof, the step specifically comprising the following sub-steps:

S301, calculating the total mutual inductance reactance between the conductor layer i and the conductor layer j within an A-phase wire in a three-phase system.

assuming that the system is in three-phase current symmetry, that is

İ₁+İ₂+İ₃+ . . . İₘ=İ_{Σ},

the wire is in three-phase symmetry after alternation and the equivalent distance between wires is D_{eq}, and the distance between the wires is considered to be much greater than the distance between each strand within a one-phase wire, then for the conductor layer i within an A phase wire, a magnetic flux linkage generated by the current in the conductor layer j is:

$$\begin{matrix}{ψ}_{aij} = {M}_{aiaj} {i}_{aj} + {M}_{aibj} {i}_{bj} + {M}_{aicj} {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] {i}_{bj} + \frac{{μ}_{0}}{2 π} [ Ln ( \frac{2 l}{{D}_{eq}} - 1 ) ] {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] ( {i}_{bj} + {i}_{cj} ) \\ = \frac{{μ}_{0}}{2 π} Ln ( \frac{{D}_{eq}}{{D}_{ij}} ) {i}_{aj}\end{matrix}$$

in a three-phase symmetric system, the total mutual inductance between the conductor layer i within an A-phase wire and the conductor layer j within the A-phase wire is

$${M}_{aiaj} = \frac{{μ}_{0}}{2 π} [ Ln ( \frac{2 l}{{D}_{ij}} - 1 ) ]$$

and in the three-phase symmetric system, the total mutual inductance reactance between the conductor layer i within the A-phase wire and the conductor layer j within the A-phase wire is

$${X}_{aij} = {μ}_{0} f Ln ( \frac{{D}_{eq}}{{D}_{ij}} ) ,$$

where f is the grid frequency, and since the system is in three-phase symmetry, Xᵢⱼ is used afterwards to represent the mutual inductance reactance between a layer i and a layer j of a certain phase, that is

$${X}_{aij} = {μ}_{0} f Ln ( \frac{{D}_{eq}}{{D}_{ij}} ) .$$

S302, calculating the self-inductance reactance of the conductor layer i within the A-phase wire in the three-phase system; and

In the above formula, by making i=j, the self-inductance reactance of the conductor layer i can be obtained

$${X}_{aii} = {μ}_{0} f Ln ( \frac{{D}_{eq}}{{D}_{ii}} ) .$$

S4, calculating the distribution of currents in each layer.

assuming that in one phase the resistances of each layer from inside to outside is r₁, r₂, r₃ . . . r₄ respectively, and taking a wire segment of unit length, wherein the voltage drops between each layer on the wire segment should be equal, denoted as V, then there is

V=r₁i₁+j(X₁₁i₁+X₁₂i₂+X₁₃i₃+X₁₄i₄)

V=r₂i₂+j(X₂₁i₁+X₂₂i₂+X₂₃i₃+X₂₄i₄)

V=r₃i₃+j(X₃₁i₁+X₃₂i₂+X₃₃i₃+X₃₄i₄)

V=r₄i₄+j(X₄₁i₁+X₄₂i₂+X₄₃i₃+X₄₄i₄),

combining the above formulas and eliminating V and D_{eq} to obtain

$$[ \begin{matrix}{r}_{1} - j {μ}_{0} f Ln \frac{{D}_{11}}{{D}_{12}} \\ {r}_{1} - j {μ}_{0} f Ln \frac{{D}_{11}}{{D}_{13}} \\ . {r}_{1} - j {μ}_{0} f Ln \frac{{D}_{11}}{{D}_{14}}\end{matrix} ] [ \begin{matrix}{i}_{1} & 0 & 0 \\ 0 & {i}_{1} & 0 \\ 0 & 0 & {i}_{1}\end{matrix} ] = [ \begin{matrix}{r}_{2} + j {μ}_{0} f Ln \frac{{D}_{12}}{{D}_{22}} & j {μ}_{0} f Ln \frac{{D}_{13}}{{D}_{23}} & j {μ}_{0} f Ln \frac{{D}_{14}}{{D}_{24}} \\ j {μ}_{0} f Ln \frac{{D}_{12}}{{D}_{23}} & {r}_{3} + j {μ}_{0} f Ln \frac{{D}_{13}}{{D}_{23}} & j {μ}_{0} f Ln \frac{{D}_{12}}{{D}_{34}} \\ j {μ}_{0} f Ln \frac{{D}_{12}}{{D}_{24}} & j {μ}_{0} f Ln \frac{{D}_{13}}{{D}_{34}} & {r}_{4} + j {μ}_{0} f Ln \frac{{D}_{14}}{{D}_{44}}\end{matrix} ] [ \begin{matrix}{i}_{2} \\ {i}_{3} \\ {i}_{4}\end{matrix} ] , \\ denoting \\ T = {[ {r}_{1} - j {μ}_{0} f Ln \frac{{D}_{11}}{{D}_{12}} {r}_{1} - j {μ}_{0} f Ln \frac{{D}_{11}}{{D}_{13}} {r}_{1} - j {μ}_{0} f Ln \frac{{D}_{11}}{{D}_{14}} ]}^{T} , \\ X = [ \begin{matrix}{r}_{2} + j {μ}_{0} f Ln \frac{{D}_{12}}{{D}_{22}} & j {μ}_{0} f Ln \frac{{D}_{13}}{{D}_{23}} & j {μ}_{0} f Ln \frac{{D}_{14}}{{D}_{24}} \\ j {μ}_{0} f Ln \frac{{D}_{12}}{{D}_{23}} & {r}_{3} + j {μ}_{0} f Ln \frac{{D}_{13}}{{D}_{23}} & j {μ}_{0} f Ln \frac{{D}_{12}}{{D}_{34}} \\ j {μ}_{0} f Ln \frac{{D}_{12}}{{D}_{24}} & j {μ}_{0} f Ln \frac{{D}_{13}}{{D}_{34}} & {r}_{4} + j {μ}_{0} f Ln \frac{{D}_{14}}{{D}_{44}}\end{matrix} ] , \\ then \\ [ \begin{matrix}{i}_{2} \\ {i}_{3} \\ {i}_{4}\end{matrix} ] = {X}^{- 1} T [ \begin{matrix}{i}_{1} & 0 & 0 \\ 0 & {i}_{1} & 0 \\ 0 & 0 & {i}_{1}\end{matrix} ] ,$$

when vectors are used for representation

$$[ \begin{matrix}{\dot{I}}_{2} \\ {\dot{I}}_{3} \\ {\dot{I}}_{4}\end{matrix} ] = {X}^{- 1} T [ \begin{matrix}{\dot{I}}_{1} & 0 & 0 \\ 0 & {\dot{I}}_{1} & 0 \\ 0 & 0 & {\dot{I}}_{1}\end{matrix} ] ,$$

by means of the solution described above, the ratio between currents of various layers is obtained, and by adding the formula

İ₁+İ₂+İ₃+İ₄=İ_{Σ}

the current distribution in each layer is calculated.

Model Effect Analysis:

Using the model calculation process described above, the current of each layer within the LGJ300/40 type wire is calculated, and the total effective value of the applied current is 700 A, and the phase angle is 0°. Comparing the calculated results with the finite element calculation results, the comparison results are shown in Table 1:

TABLE 1
Comparison table of calculation results

| | the first layer | the second layer | the third layer | the fourth layer |
|---|---|---|---|---|
| finite | İ₁′ = 0.65 ∠ −29.0 | İ₂′ = 0.67 ∠ −20.9 | İ₃′ = 28.91 ∠ −5.0 | İ₄ ′ = 29.17 ∠ +4.0 |
| element | | | | |
| μᵣ = 1000 | İ₁′ = 0.74 ∠ −16.3 | İ₂′ = 0.74 ∠ −16.2 | İ₃′ = 28.93 ∠ −4.5 | İ₄′ = 29.12 ∠ +2.9 |
| error % | 13.31 | 10.51 | 0.08 | −0.19 |
| μᵣ = 2000 | İ₁′ = 0.70 ∠ −25.8 | İ₂′ = 0.70 ∠ −25.7 | İ₃′ = 28.95 ∠ −4.5 | İ₄′ = 29.14 ∠ +2.9 |
| error % | 8.32 | 5.67 | 0.12 | −0.11 |

Considering that the steel-cored aluminum stranded wire has a non-uniform current distribution at the power frequency, and the current mainly flows through the aluminum conductor layer, so that the heat generation inside the conductors mainly occurs in the aluminum conductor layer. Although the calculation result of the patent of the present invention differs greatly in the simulation results of the steel-cored conductor and the finite element, for the aluminum conductor layer having a large heat generation rate, by correcting the relative magnetic permeability, the error can be reduced to 0.125%. In addition, the method can reflect the phase difference between the conductors in each layer. Therefore, when calculating the internal radial temperature distribution of an overhead wire or calculating the temperature of a steel core, the calculation method in this patent can be used to calculate the current distribution and the heat generation rate of each layer.

The above-described embodiments are preferred embodiments of the present invention; however, the embodiments of the present invention are not limited to the above-described embodiments, and any other change, modification, replacement, combination, and simplification made without departing from the spirit, essence, and principle of the present invention should be an equivalent replacement and should be included within the scope of protection of the present invention.

1. A method for determining the amplitude and phase of a stratified current of an overhead wire, characterized in that the method comprises:
S1, determining the specification, the size and main technical parameters of a wire, the step specifically being as follows:
S101, determining the number of layers of the overhead wire and the number of conductors in each layer and the planned size thereof; and
S102, determining the material of the conductors in each layer and the corresponding resistivity and magnetic permeability;
S2, calculating mutual inductances between conductors within a single-phase wire and the self-inductance thereof, the step specifically being as follows:
S201, calculating the mutual inductance between a conductor layer i and a conductor layer j within the single-phase wire; and
S202, calculating the self-inductance of the conductor layer i within the single-phase wire;
S3, calculating mutual inductance reactance between conductors within the single-phase wire in a three-phase system and the self-inductance reactance thereof, the step specifically being as follows:
S301, calculating the total mutual inductance reactance between the conductor layer i and the conductor layer j within an A-phase wire in a three-phase system; and
S302, calculating the self-inductance reactance of the conductor layer i within the A-phase wire in the three-phase system; and
S4, calculating the distribution of currents in conductors in each layer within the single-phase wire.

2. The method for determining the amplitude and phase of a stratified current of an overhead wire of claim 1, characterized in that step S101 is specifically as follows:
numbering the wires and determining the radius of the overhead wire and the radius of each conductor, wherein each phase of the three-phase wire has m layers, which are numbered, from inside to outside, as 1, 2, . . . m, there are n conductors in each layer within a wire, no distinction is made between conductors in each layer, and the three-phase wires are only distinguished by subscripts a, b and c in derivation; and
in terms of current, using İᵢ to indicate the total current of the layer i, and using İᵢ′ to indicate the current on a conductor in the layer i, that is İᵢ=nİᵢ′,
where n is the number of conductors in the layer i, and İᵢ′ appears only in the result analysis to compare effects of a skin effect.

3. The method for determining the amplitude and phase of a stratified current of an overhead wire of claim 1, characterized in that step S102 is specifically as follows:
determining the resistivity and magnetic permeability of various conductors based on if the overhead wire is a steel-cored aluminum stranded wire, an aluminum stranded wire or a copper wire.

4. The method for determining the amplitude and phase of a stratified current of an overhead wire of claim 1, characterized in that the calculation formula for the mutual inductance Mₐᵢₐⱼ in step S201 is specifically as follows:
$${M}_{aiaj} = \frac{{μ}_{0}}{2 π} [ Ln ( \frac{2 l}{{D}_{ij}} - 1 ) ] , \\ wherein {D}_{ij} = \sqrt[mn]{{\prod }_{k = 1}^{m} {\prod }_{i = 1}^{n} [ {r}_{i}^{2} + {r}_{j}^{2} - 2 {r}_{i} {r}_{j} cos ( {θ}_{ik} - {θ}_{j 1} ) ]} ,$$
where m is the number of conductors in the layer i, n is the number of conductors in the layer j, Dᵢⱼ is a geometric mean of distances between conductors located in the layer i and the layer j respectively, rᵢ is the distance from the center of circle of a single conductor in the layer i to the center of the wire, rⱼ is the distance from the center of circle of the single conductor in the layer j to the center of the wire, and θᵢₖ−θⱼ₁ is an opening angle between the center of circle of the k^{th} conductor in the layer i and the center of circle of the 1^{st} conductor in the layer j, relative to the center of circle of the wire.

5. The method for determining the amplitude and phase of a stratified current of an overhead wire of claim 1, characterized in that the calculation formula for the self-inductance Lₐᵢₐᵢ in step S202 is specifically as follows:
$${L}_{aiaj} = \frac{{μ}_{0}}{2 π} [ Ln ( \frac{2 l}{{D}_{ij}} - 1 ) ] , \\ wherein , {D}_{ii} = \sqrt[m]{{r}_{eq} {\prod }_{k = 2}^{m} [ {r}_{i}^{2} + {r}_{1}^{2} - 2 {r}_{i} {r}_{1} cos ( {θ}_{ik} - {θ}_{i 1} ) ]}$$
where m is the number of conductors in the layer i, Dᵢᵢ is a geometric mean of distances between conductors in the layer i, rᵢ is the distance from the center of circle of a single conductor in the layer i to the center of the wire, θᵢₖ−θᵢ₁ is an opening angle between the center of circle of the k^{th} conductor in the layer i and the center of circle of the 1^{st} conductor in the layer i, relative to the total center of circle of the wire, and r_{eq} is an equivalent radius of the first conductor in the layer i.

6. The method for determining the amplitude and phase of a stratified current of an overhead wire of claim 1, characterized in that step S301 is specifically as follows:
assuming that the system is in three-phase current symmetry, that is
iₐᵢ+i_{bi}+i_{ci}=0
the wire is in three-phase symmetry after alternation and the equivalent distance between wires is D_{eq}, and the distance between the wires is much greater than the distance between each strand within a one-phase wire, then for the conductor layer i within an A phase wire, a magnetic flux linkage generated by the current in the conductor layer j is:
$$\begin{matrix}{Ψ}_{aij} = {M}_{aiaj} {i}_{aj} + {M}_{aibj} {i}_{bj} + {M}_{aicj} {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] {i}_{bj} + \frac{{μ}_{0}}{2 π} [ Ln ( \frac{2 l}{{D}_{eq}} - 1 ) ] {i}_{cj} \\ = \frac{{μ}_{0}}{2 π} [ Ln ( \frac{2 l}{{D}_{ij}} - 1 ) ] {i}_{aj} + \frac{{μ}_{0}}{2 π} [ Ln ( \frac{2 l}{{D}_{eq}} - 1 ) ] ( {i}_{bj} + {i}_{cj} ) \\ = \frac{{μ}_{0}}{2 π} Ln ( \frac{{D}_{eq}}{{D}_{ij}} ) {i}_{aj}\end{matrix}$$
then, in a three-phase symmetric system, the total mutual inductance between the conductor layer i within an A-phase wire and the conductor layer j within the A-phase wire is:
$${M}_{aiaj} = \frac{{μ}_{0}}{2 π} [ Ln ( \frac{2 l}{{D}_{ij}} - 1 ) ]$$
and in the three-phase symmetric system, the total mutual inductance reactance between the conductor layer i within the A-phase wire and the conductor layer j within the A-phase wire is:
$${X}_{aij} = {μ}_{0} f Ln ( \frac{{D}_{eq}}{{D}_{ij}} ) .$$

7. The method for determining the amplitude and phase of a stratified current of an overhead wire of claim 6, characterized in that step S302 is specifically as follows:
in the mutual inductance reactance
$${X}_{aij} = {μ}_{0} f Ln ( \frac{{D}_{eq}}{{D}_{ij}} )$$
making i=j to obtain the self-inductance reactance of the conductor layer i
$${X}_{aii} = {μ}_{0} f Ln ( \frac{{D}_{eq}}{{D}_{ii}} ) .$$

8. The method for determining the amplitude and phase of a stratified current of an overhead wire of claim 1, characterized in that step S4 is specifically as follows:
assuming that in one phase the resistances of each layer from inside to outside is r₁, r₂, r₃ . . . rₘ respectively, and taking a wire segment of unit length, wherein the voltage drops between each layer on the wire segment should be equal, denoted as V, then there is
$$V = {r}_{1} {i}_{1} + j ( {X}_{11} {i}_{1} + {X}_{12} {i}_{2} + {X}_{13} {i}_{3} + … {X}_{1 m} {i}_{m} )$$
$$V = {r}_{2} {i}_{2} + j ( {X}_{21} {i}_{1} + {X}_{22} {i}_{2} + {X}_{23} {i}_{3} + … {X}_{2 m} {i}_{m} )$$
$$V = {r}_{3} {i}_{1} + j ( {X}_{31} {i}_{1} + {X}_{32} {i}_{2} + {X}_{33} {i}_{3} + … {X}_{3 m} {i}_{m} )$$
$$…$$
$$V = {r}_{m} {i}_{1} + j ( {X}_{m 1} {i}_{1} + {X}_{m 2} {i}_{2} + {X}_{m 3} {i}_{3} + … {X}_{ m m} {i}_{m} ) ,$$
combining the above formulas and eliminating V and D_{eq} to obtain
$$[ \begin{matrix}{r}_{1} - j {μ}_{0} f Ln \frac{{D}_{11}}{{D}_{12}} \\ {r}_{1} - j {μ}_{0} f Ln \frac{{D}_{11}}{{D}_{13}} \\ … \\ {r}_{1} - j {μ}_{0} f Ln \frac{{D}_{11}}{{D}_{1 m}}\end{matrix} ] [ \begin{matrix}{i}_{1} & 0 & 0 & … & 0 \\ 0 & {i}_{1} & 0 & … & 0 \\ 0 & 0 & {i}_{1} & … & 0 \\ … & & & & \\ 0 & 0 & 0 & … & {i}_{1}\end{matrix} ] = [ \begin{matrix}{r}_{2} + j {μ}_{0} f Ln \frac{{D}_{12}}{{D}_{22}} & j {μ}_{0} f Ln \frac{{D}_{13}}{{D}_{23}} & … & j {μ}_{0} f Ln \frac{{D}_{1 m}}{{D}_{2 m}} \\ j {μ}_{0} f Ln \frac{{D}_{12}}{{D}_{23}} & {r}_{3} + j {μ}_{0} f Ln \frac{{D}_{13}}{{D}_{23}} & … & j {μ}_{0} f Ln \frac{{D}_{12}}{{D}_{3 m}} \\ … & & & \\ j {μ}_{0} f Ln \frac{{D}_{12}}{{D}_{2 m}} & j {μ}_{0} f Ln \frac{{D}_{13}}{{D}_{3 m}} & … & {r}_{4} + j {μ}_{0} f Ln \frac{{D}_{1 m}}{{D}_{m m}}\end{matrix} ] [ \begin{matrix}{i}_{2} \\ {i}_{3} \\ … \\ {i}_{m}\end{matrix} ] , \\ T = {[ {r}_{1} - j {μ}_{0} f Ln \frac{{D}_{11}}{{D}_{12}} {r}_{1} - j {μ}_{0} f Ln \frac{{D}_{11}}{{D}_{13}} … {r}_{1} - j {μ}_{0} f Ln \frac{{D}_{11}}{{D}_{1 m}} ]}^{T} \\ denoting \\ X = [ \begin{matrix}{r}_{2} + j {μ}_{0} f Ln \frac{{D}_{12}}{{D}_{22}} & j {μ}_{0} f Ln \frac{{D}_{13}}{{D}_{23}} & … & j {μ}_{0} f Ln \frac{{D}_{1 m}}{{D}_{2 m}} \\ j {μ}_{0} f Ln \frac{{D}_{12}}{{D}_{23}} & {r}_{3} + j {μ}_{0} f Ln \frac{{D}_{13}}{{D}_{23}} & … & j {μ}_{0} f Ln \frac{{D}_{12}}{{D}_{3 m}} \\ … & & & \\ j {μ}_{0} f Ln \frac{{D}_{12}}{{D}_{2 m}} & j {μ}_{0} f Ln \frac{{D}_{13}}{{D}_{3 m}} & … & {r}_{4} + j {μ}_{0} f Ln \frac{{D}_{1 m}}{{D}_{m m}}\end{matrix} ] \\ then [ \begin{matrix}{i}_{2} \\ {i}_{3} \\ … \\ {i}_{4}\end{matrix} ] = {X}^{- 1} T [ \begin{matrix}{i}_{1} & 0 & 0 & … & 0 \\ 0 & {i}_{1} & 0 & … & 0 \\ 0 & 0 & {i}_{1} & … & 0 \\ … & & & & \\ 0 & 0 & 0 & … & {i}_{1}\end{matrix} ] ,$$
when vectors are used for representation
$$[ \begin{matrix}{\dot{I}}_{2} \\ {\dot{I}}_{3} \\ … \\ {\dot{I}}_{4}\end{matrix} ] = {X}^{- 1} T [ \begin{matrix}{\dot{I}}_{1} & 0 & 0 & … & 0 \\ 0 & {\dot{I}}_{1} & 0 & … & 0 \\ 0 & 0 & {\dot{I}}_{1} & … & 0 \\ … & & & & \\ 0 & 0 & 0 & … & {\dot{I}}_{1}\end{matrix} ] ,$$
by means of the solution described above, the ratio distribution between currents of each layer is obtained, and by adding the formula
İ₁+İ₂+İ₃+ . . . İₘ=İ_{Σ}
the current distribution in each layer is calculated.
